(19) United States
(12) Patent Application Publication
(10) Pub. No.: US 2026/0239524 A1
(43) Pub. Date: Aug. 13, 2026

(54) MEANS TO IMPROVE THE THERMAL PERFORMANCE OF A PRINTED ELECTRONICS LED LIGHT SOURCE

(71) Applicant: SIGNIFY HOLDING B.V., Eindhoven (NL)

(72) Inventors: SIMON JACOBUS MARIA KUPPENS, GELDROP (NL); GEORGES MARIE CALON, EINDHOVEN (NL); PETER HENRI BANCKEN, HEEZE (NL)

(21) Appl. No.: 19/159,636

(22) PCT Filed: Feb. 26, 2024
(86) PCT No.: PCT/EP2024/054751

§ 371 Date: Aug. 26, 2025

(30) Foreign Application Priority Data
Mar. 2, 2023 (EP) 23159668.5

(51) Int. Cl. H05K 1/02

(52) U.S. Cl. CPC H05K 1/0203; H05K 2201/10106

(57) ABSTRACT

The invention provides an electronics arrangement (2000) comprising a support board (200), an electrically conductive printed track (80), an extended printed region (70), an electronic element (90), and a thermally conductive layer (400), wherein: the support board (200) is configured to support the electrically conductive printed track (80), the extended printed region (70), and the electronic element (90); wherein the electrically conductive printed track (80) is configured on the support board (200); wherein the electrically conductive printed track (80) comprises an electrically conductive printed track material (81); wherein the electronic element (90) is configured in electrical contact with the electrically conductive printed track (80); wherein the electronic element (90) comprises a cross-sectional area A_{E}, defined parallel to the support board (200);

wherein the extended printed region (70) is configured on the support board (200); wherein the extended printed region (70) comprises an extended printed region material (71); wherein the extended printed region (70) comprises a cross-sectional area A_{T} defined parallel to the support board (200); and wherein the thermally conductive layer (400) is at least partly configured on at least part of the extended printed region (70); wherein the thermally conductive layer (400) comprises a thermally conductive layer material (410) wherein the thermally conductive layer (400) is in thermal contact with the electronic element (90), wherein the thermally conductive layer (400) comprises a cross-sectional area As defined parallel to the support board (200), wherein Aₛ/A_{T}≤1.1, and wherein 1.5≤A_{S}/A_{E}≤30.

### FIELD OF THE INVENTION

The invention relates to an electronics arrangement. The invention further relates to a light generating system comprising the electronics arrangement. The invention further relates to a lighting device comprising the light generating system. The invention further relates to a method of manufacturing the electronic arrangement.

### BACKGROUND OF THE INVENTION

Printed electronics are known in the art. For instance, US20150325755A1, describes techniques for attaching SMDs to a flexible substrate using conductive epoxy bond pads. Each bond pad includes a set of elongated strips of conductive epoxy that are applied and cured onto the flexible substrate in an adjacent and parallel fashion. The bond pads are used to attach SMDs to the flexible substrate and also provide the conductive contacts for a printed circuit. A circuit may be printed on the flexible substrate using conductive ink that partially covers the bond pads, leaving a portion of the pads exposed. A second layer or strip of conductive epoxy may be applied over and across the exposed portions of the bond pad strips in order to attach an SMD. The number, size, and orientation of the epoxy bond pad strips may be determined by the amount of bending the flexible substrate is expected to withstand and/or the orientation of the bend.

### SUMMARY OF THE INVENTION

The manufacturing of Printed Circuit Boards (PCB) may include a wet chemical process that requires a lot of energy and chemicals, and that creates chemical waste. The environmental footprint of manufacturing PCB's can be strongly reduced by applying direct printing of the tracks onto a substrate, i.e., Printed Electronics. Conventional tracks are made as wide as possible to create good heat spreading close to electronic elements, such as LEDs. The full surface of a PCB substrate is covered with copper of which small portions are etched away to create a circuit. Such a process is costly and wasteful. In contrast, in printed electronics paste is added only in places where it is needed. In Printed Electronics the current conducting tracks on a PCB or LED board are made by printing a paste containing micro- or nano particles of a conductive metal (usually Ag or Cu). After curing a conductive path is created. Compared to metallic Cu, which is standardly used in PCBs, the electric and thermal conductivity of the printed layer is considerably worse. This creates additional electric losses, which can be partly mitigated by adding more paste (wider & thicker layers). However, this adds cost as more printing paste is required. Furthermore, the thermal impact is not easily reduced by making the tracks wider, and making the conductive tracks of a printed LED board as wide as on a conventional PCB would lead to very high and non-competitive costs.

Hence, the challenge is to create improved electronic and thermal performance for the incumbent LED board with as little as possible printing paste. One solution could lead to a design with narrow tracks. With respect to the electronic performance this can be done by choosing layouts that lead to low currents and making the tracks as narrow as possible. However, for the thermal performance, this only partially works as low currents per LED can still lead to high heat loads per LED.

Hence, it is an aspect of the invention to provide an alternative electronics arrangement, which preferably further at least partly obviates one or more of above-described drawbacks. The present invention may have as object to overcome or ameliorate at least one of the disadvantages of the prior art, or to provide a useful alternative.

According to a first aspect, the invention provides an electronics arrangement comprising a support board, an electrically conductive printed track, and extended printed region, an electronic element, and a thermally conductive layer. The support board may especially be configured to support the electrically conductive printed track, the extended printed region, and the electronic element. More especially, the electrically conductive printed track and the extended printed region may be configured on a first face of the support board. In embodiments, the electrically conductive printed track may comprise an electrically conductive printed track material. Likewise, in embodiments, the extended printed region may comprise an extended printed region material. The electronic element may, in embodiments, be configured in electrical contact with the electrically conductive printed track. Further, in embodiments, the electronic element may comprise a cross-sectional area (A_{E}) defined parallel to the (first face of the) support board. Yet further, in embodiments, the extended printed region may comprise a cross-sectional area (A_{T}) defined parallel to the (first face of the) support board. In embodiments, the extended printed region may especially be configured in thermal contact with the electronic element. Optionally, the extended printed region may also be configured in electrical contact with the electrically conductive printed track. In embodiments, the thermally conductive layer may at least partly be configured on (part of the electrically conductive printed track and) at least part of the extended printed region. The thermally conductive layer may especially comprise a thermally conductive layer material. More especially, in embodiments, the thermally conductive layer may be in thermal contact with the electronic element. In embodiments, the thermally conductive layer may comprise a cross-sectional area (A_{S}) defined parallel to the (first face of the) support board. Especially, in embodiments, A_{S}/A_{T}≤1.1. Further, in embodiments, 1.5≤A_{S}/A_{E}≤30. In yet further embodiments, A_{S}/A_{T}≤1.1, and 1.5≤A_{S}/A_{E}≤30. Hence, in specific embodiments, the invention provides an electronics arrangement comprising a support board, an electrically conductive printed track, an extended printed region, an electronic element, and a thermally conductive layer, wherein: the support board may be configured to support the electrically conductive printed track, the extended printed region, and the electronic element; wherein the electrically conductive printed track may be configured on the support board; wherein the electrically conductive printed track may comprise an electrically conductive printed track material; wherein the electronic element may be configured in electrical contact with the electrically conductive printed track; wherein the electronic element may comprise a cross-sectional area A_{E}, defined parallel to the support board; wherein the extended printed region may be configured on the support board; wherein the extended printed region may comprise an extended printed region material; wherein the extended printed region may comprise a cross-sectional area A_{T} defined parallel to the support board; and wherein the thermally conductive layer may be at least partly configured on at least part of the extended printed region; wherein the thermally conductive layer may comprise a thermally conductive layer material, wherein the thermally conductive layer may be in thermal contact with the electronic element, wherein the thermally conductive layer may comprise a cross-sectional area A_{S} defined parallel to the support board, wherein A_{S}/A_{T}≤1.1, and wherein 1.5≤A_{S}/A_{E}≤30. Especially, in embodiments the electronics arrangement comprises a plurality of electronic elements, of which at least one comprises a solid state light source. in specific embodiments, Hence, the invention also provides an electronics arrangement comprising a support board, an electrically conductive printed track, an extended printed region, one or more electronic elements, and a thermally conductive layer, wherein: the support board may be configured to support the electrically conductive printed track, the extended printed region, and at least one of the electronic elements; wherein the electrically conductive printed track may be configured on the support board; wherein the electrically conductive printed track may comprise an electrically conductive printed track material; wherein the at least one electronic element may be configured in electrical contact with the electrically conductive printed track; wherein the at least one electronic element may comprise a cross-sectional area A_{E}, defined parallel to the support board; wherein the extended printed region may be configured on the support board; wherein the extended printed region may comprise an extended printed region material; wherein the extended printed region may comprise a cross-sectional area A_{T} defined parallel to the support board; and wherein the thermally conductive layer may be at least partly configured on at least part of the extended printed region; wherein the thermally conductive layer may comprise a thermally conductive layer material, wherein the thermally conductive layer may be in thermal contact with the at least one electronic element, wherein the thermally conductive layer may comprise a cross-sectional area A_{S} defined parallel to the support board, wherein A_{S}/A_{T}≤1.1, and wherein 1.5≤A_{S}/A_{E}≤30. Here below, the at least one electronic element may further be indicated as “electronic element”. The at least one electronic element may comprise a solid state light source. As indicated above, the electronics arrangement may comprise a plurality of electronic elements. At least one of this plurality of electronic elements may thus be the “at least one electronic element”. Further, at least one of this plurality of electronic elements may comprise a solid state light source. In specific embodiments, the at least one electronic element may comprise a solid state light source, and in other embodiments, this may not be the case. Further, there may be two or more electronic elements which may be in contact with a respective thermally conductive layer.

With such embodiments, an electronics arrangement, such as a printed circuit board, with improved thermal management may be provided. The electronics arrangement of the invention may have relatively narrow printed tracks, which may require relatively small amounts of printed track material. This may be beneficial as (conventional) printed track material may be relatively expensive, whereas materials used for the thermally conductive layer may be cheaper. Further, conventional printed tracks are produced as wide as possible (to create good heat spreading) and excess material is later removed. The invention described herein may avoid the step of removing excess material as the electrically conductive track, the extended printed region, and the thermally conductive layer may be added (directly and only) in places where it is needed. Thus, the invention may provide a cost and energy efficient electronics arrangement. Furthermore, the thermal conductivity of the thermally conductive layer may be higher than that of the printed tracks, therefore, the thermally conductive layer may act as a more efficient heat spreader. Hence, the present invention may provide an electronics arrangement with improved thermal management, which may in turn have a positive effect on the (thermal) performance of the electronics arrangement.

In embodiments, the invention provides an electronics arrangement comprising a support board, an electrically conductive printed track, an extended printed region, an electronic element, and a thermally conductive layer.

The support board may, in embodiments, be configured to support the electrically conductive printed track, the extended printed region, and the electronic element. Hence, in embodiments, the support board may comprise a solid structure that may serve as a base for the electronics arrangement. For example, in embodiments, the support board may comprise a plank, a panel, a plate, or a strip (such as a LED strip). Especially, the support board may have a first face. The (first face of the) support board may have cross-sectional dimensions (D). Furthermore, the support board may have a height (H) defined perpendicular to the first face. In embodiments, the height (H) of the support board may be substantially smaller than the cross-sectional dimensions (D), i.e., H<D, such as H≤0.5*D, like H≤0.2*D.

In embodiments, the support board may comprise one or more materials selected from the group comprising a metal, wood, paper, (fiber) glass, a ceramic material, or a polymeric material. In embodiments, the support board may comprise a coating. Further, in embodiments, the support board may be rigid. In other embodiments, the support board may be flexible. Especially, herein the support board may be flexible.

The electrically conductive printed track may be configured on the support board. Especially, in embodiments, the electrically conductive printed track may be printed onto the support board. Hence, the support board and the electrically conductive printed track may be physically connected.

The electrically conductive printed track may, in embodiments, comprise an electrically conductive printed track material. Especially, the electrically conductive printed track material may comprise one or more materials selected from the group comprising (metallic) copper, (metallic) gold, (metallic) aluminum, and (metallic) silver. In embodiments, the electrically conductive printed track material may (also) comprise one or more (semi-) conductive polymers, such as polypyrrole, polythiophene, polyaniline, and poly(3,4-ethylene dioxitiophene), doped with poly(styrene sulfonate) (PEDOT:DSS). Further, in embodiments, the electrically conductive printed track material may comprise additional electrically conductive particles (see also further below) to (help) facilitate electrical coupling of electronic elements. Yet further, in embodiments, the electrically conductive printed track material may comprise a thermally conductive material, see also further below. Hence, the electrically conductive printed track material may, in embodiments, be an electrically and thermally conductive material.

In embodiments, the electronic element may be configured in electrical contact with the electrically conductive printed track. Hence, the electronic element may be configured such that an electrical current may flow between the electrically conductive printed track and the electronic element. For example, in embodiments, the electronic element may be configured in direct physical contact with the electrically conductive printed track. In another example, the electronic element may not be configured in physical contact with the electrically conductive printed track, but the electronic element may be configured in electrical contact with the electrically conductive printed track through intermediate materials, such as the thermally conductive layer.

The electronic element may, in embodiments, comprise a cross-sectional area (A_{E}) defined parallel to the (first face of the) support board. Especially, the electronic element cross-sectional area (A_{E}) may, in embodiments, be at most 500 mm², such as at most 100 mm². More especially, in embodiments, the electronic element cross-sectional area (A_{E}) may be selected from the range of 0.1-250 mm², such as from the range of 0.1-100 mm², like from the range of 1-10 mm². Would the electronic element have different cross-sectional areas in dependence of its height, the cross-sectional area (A_{E}) may refer to the largest cross-sectional area.

An electrical component may be a component that (directly) converts the energy from an electrical current into another form of energy, e.g., heat, light, motion, etc. An electronic component is an electrical component that may (additionally or alternatively) control the flow of electrons from an electrical current. Herein, the term electrical component may especially refer to an electronic component. The electronic component may include an active or a passive electronic component. In embodiments, the electronic component may comprise a sub-PCB board (or additional PCB board) comprising one or more electronic components. An active electronic component may be any type of circuit component with the ability to electrically control electron flow (electricity controlling electricity). Examples thereof are diodes, especially light emitting diodes (LEDs). LEDs are herein also indicated with the more general term solid state lighting devices or solid state light sources. Hence, in embodiments the electronic component comprises an active electronic component. Especially, the electronic component comprises a solid state light source. Other examples of active electronic components may include power sources, such as a battery, a piezo-electric device, an integrated circuit (IC), and a transistor. In embodiments, the electronic component comprises a driver. In yet other embodiments, the electronic component may include a passive electronic component. Components incapable of controlling current by means of another electrical signal are called passive devices. Resistors, capacitors, inductors, transformers, etc. can be considered passive devices. In embodiments, the electronic component may include an RFID (Radio-frequency identification) chip. A RFID chip may be passive or active. Especially, the electronic component may include one or more of a solid state light source (such as an LED), a RFID chip, and an IC. The term “electronic component” may also refer to a plurality of alike or a plurality of different electronic components. In embodiments, the electrical arrangement may comprise at least three, such as at least four, such as at least 10 electrical components. In embodiments, the electrical components may at least comprise one or more ICs and one or more resistors.

Such electrical component may be an electrical component that during operation generates heat, such as e.g. a capacitor, an inductor, a voltage regulator, an amplifier circuit, an integrated circuit, a central processing unit, a microprocessor unit, a power transistor, a field-effect transistor (“FET”, especially a metal-oxide semiconductor field-effect transistor (“MOS-FET”)), a transformer, a resistor, or a diode (especially a LED). Moreover, such electrical components may be electrical components that are sensitive to heat (i.e., affected in terms of lifespan and/or performance by high temperatures), such as e.g. a capacitor, a resistor, a diode (such as a crystal diode), or a sensor. In embodiments comprising a PCB, such electrical components may be functionally and electrically coupled to the PCB.

Similarly to the electrically conductive printed track, the extended printed region may also, in embodiments, be configured on the support board. Especially, in embodiments, the extended printed region may be printed on the support board. Hence, the extended printed region and the support board may be physically connected. In embodiments, the extended printed region may especially be configured around part of the electrically conductive printed track, i.e., a part of the electrically conductive printed track may be (partially) surrounded by the extended printed region. Especially, the extended printed region may locally extend from the electrically conductive printed track, i.e., in embodiments, the extended printed region may serve as a local extension of the electrically conductive printed track. In embodiments, the extended printed region and the electrically conductive printed track may especially be (printed) in physical contact with each other, i.e., the extended printed region and the electrically conductive printed track may be printed as a uniform section (“monolithic section”). However, in other embodiments, the extended printed region and the electrically conductive printed track may not necessarily be in physical contact with each other, i.e., the extended printed region and the electrically conductive printed track may be printed as separate sections.

Further, in embodiments, the extended printed region may be configured in thermal contact with the electronic element (and the electrically conductive printed track). For example, in embodiments, the electronic element may be configured in direct physical contact with the extended printed region. In another example, the electronic element may not be configured in physical contact with the extended printed region, but the electronic element may be configured in thermal contact with the extended printed region through intermediate materials, such as the thermally conductive layer. Yet further, in embodiments, the extended printed region may optionally be configured in electrical contact with the electrically conductive printed track.

The extended printed region may, in embodiments, comprise an extended printed region material. Especially, the extended printed region material may comprise one or more materials selected from the group comprising (metallic) copper, (metallic) gold, (metallic) aluminum, and (metallic) silver. In embodiments, the extended printed region material may (also) comprise one or more (semi-) conductive polymers, such as polypyrrole, polythiophene, polyaniline, and poly(3,4-ethylene dioxitiophene), doped with poly(styrene sulfonate) (PEDOT:DSS). Further, In embodiments, the extended printed region material may comprise additional electrically conductive particles (see also further below) to (help) facilitate electrical coupling of electronic elements. Yet further, in embodiments, the extended printed region material may comprise a thermally conductive material, see also further below. Hence, the extended printed region material may, in embodiments, be an electrically and thermally conductive material, see also further below.

In embodiments, the electrically conductive printed track material and the extended printed region material may essentially be the same material. However, in other embodiments, the electrically conductive printed track material and the extended printed region material may be different.

Further, in embodiments, the extended printed region may comprise a cross-sectional area (A_{T}) defined parallel to the (first face of the) support board. Especially, the extended printed region cross-sectional area (A_{T}) may, in embodiments, be at least 2 mm², such as at least 10 mm². More especially, in embodiments, the extended printed region cross-sectional area (A_{T}) may be at most 1000 mm², such as at most 800 mm². In embodiments, the extended printed region cross-sectional area (A_{T}) may be selected from the range of 1-1000 mm², such as from the range of 5-500 mm², like from the range of 15-400 mm²

In embodiments, the electronics arrangement may comprise a thermally conductive layer. The thermally conductive layer may comprise a thermally conductive layer material. In embodiments, the thermally conductive layer material may comprise a thermally conductive material, such that the thermally conductive layer may be configured to dissipate heat. Especially, the thermally conductive layer may be configured in thermal contact (such as in direct physical contact) with the electronic element. In such a way, in embodiments, the thermally conductive layer may act as a heat spreader for the electronic element.

The thermally conductive layer may, in embodiments, be at least partly configured on at least part of the extended printed region described above. In embodiments, at least part of (, especially all of) the thermally conductive layer may be configured on the extended printed region, such that it may cover at least 25%, such as especially at least 50% of the extended printed region, such as at least 75% of the extended printed region, like at least 90% of the extended printed region. Especially, in embodiments, the thermally conductive layer may cover at least 95% of the extended printed region, such as at least 98% of the extended printed region. In some embodiments, the thermally conductive layer may (even) cover 100% of the extended printed region. In some embodiments, part of the thermally conductive layer may be configured not on the extended printed region. For example, in embodiments, the thermally conductive layer may be configured (slightly) ‘spilling over’ the extended printed region, i.e., the thermally conductive layer may be deposited extending (slightly) past the extended printed region.

Further, in embodiments, part of the thermally conductive layer may (also) be configured on part of the electrically conductive printed track. Especially, the thermally conductive layer may be configured on the part(s) of the electrically conductive printed track that may be (partially) surrounded by the (local) extended printed region.

The thermally conductive layer may comprise a (layer) cross-sectional area (A_{S}) defined parallel to the (first face of the) support board. As mentioned above, the thermally conductive layer may be at least partly configured on (part of the electrically conductive printed track and) at least part of the extended printed region. Therefore, in embodiments, A_{S}/A_{T}≤1.1, such as A_{S}/A_{T}≤1.05, like A_{S}/A_{T}≤1. In embodiments, A_{S}/A_{T}≥0.25, more especially A_{S}/A_{T}≥0.4, such as A_{S}/A_{T}≥0.6, like A_{S}/A_{T}≥0.8. In some embodiments, the layer cross-sectional area (A_{S}) may (essentially) be equal to the extended printed region cross-sectional area (A_{T}), such that the thermally conductive layer may cover all of the extended printed region, i.e., A_{S}=A_{T}. Hence, in such embodiments, the thermally conductive layer may be configured on the extended printed region, such that it may cover 100% of the extended printed region. However, the thermally conductive layer may also, in embodiments, cover part of the electrically conductive printed layer. In other embodiments, the thermally conductive layer may slightly spill over (or “hang over”, or “extend over”) the extended printed region. Therefore, in embodiments, the layer cross-sectional area (A_{S}) may be slightly larger than the extended printed region cross-sectional area (A_{T}), i.e., A_{S}>A_{T}. In yet other embodiments, the thermally conductive layer may not cover all of the extended printed region, i.e., A_{S}<A_{T} (see also further below). Hence, in such embodiments, the thermally conductive layer may be configured on the extended printed region, such that it may cover at least 50%, but excluding 100% of the extended printed region.

In embodiments, the layer cross-sectional area (A_{S}) may further correlate to the electronic element cross-sectional area (A_{E}). A relatively large electronic element may, in embodiments, require a larger layer cross-sectional area (A_{S}) (for sufficient heat dissipation) than a smaller electronic element. However, the ratio of the electronic element cross-sectional area (A_{E}) to the layer cross-sectional area (A_{S}) may also depend on the type of electronic elements, and on the heat load on the electronic element. In embodiments, 0.5≤A_{S}/A_{E} and/or in embodiments A_{S}/A_{E}≤50. Yet, in embodiments, especially, 1.5≤A_{S}/A_{E}≤50, such as 1.5≤A_{S}/A_{E}≤30, like 2.5≤A_{S}/A_{E}≤15. Hence, in embodiments, A_{S}/A_{E} may be at least 1.5, such as at least 2.5, like at least 5, especially at least 10.

As mentioned above, in embodiments, the support board may be flexible. In specific embodiments, the support board may comprise a flexible printed circuit board. Hence, in such embodiments, the support board may comprise a flexible material suitable for use as a printed circuit board, such as a polymeric film (e.g. a polyimide (PI) or polyester (PET) film).

Further, the thermally conductive layer material, the electrically conductive printed track material, and the extended printed region material may each be thermally conductive, i.e., may each have a thermal conductiveness. Herein, the thermal conductiveness (C) of a component may be defined by the thermal conductivity (k) of its respective materials and its respective thickness (t), especially C=k*t. In embodiments, the thermally conductive layer may have a first thermal conductiveness C₁. More especially, the thermally conductive layer material may have a first thermal conductivity k₁, and the thermally conductive layer may have a layer thickness (tₛ). Further, in embodiments, the thermally conductive printed track may have a second thermal conductiveness C₂. Especially, the thermally conductive printed track material may have a second thermal conductivity k₂, and the thermally conductive printed track may have a track thickness (tₜ). Yet further, in embodiments, the extended printed region may have a third thermal conductiveness C₃. More especially, the extended printed region material may have a third conductivity k₃, and the extended printed region may have a region thickness (tᵣ). In embodiments, the third thermal conductiveness C₃ may be larger than or equal to the second thermal conductiveness C₂. Especially, in specific embodiments, the second thermal conductiveness C₂ and the third thermal conductiveness C₃ may be substantially equal. Further, in embodiments, the first thermal conductiveness C₁ may be larger than the second thermal conductiveness C₂, and the third thermal conductiveness C₃. Especially, in embodiments, C₁/C₂≥1 and C₁/C₃≥1, such as C₁/C₂≥2 and C₁/C₃≥2, like C₁/C₂≥5 and C₁/C₃≥5. Hence, in specific embodiments, (a) the thermally conductive layer may have a first thermal conductiveness C₁, a first thermal conductivity k₁, and a layer thickness (tₛ), wherein C₁=k₁*tₛ; (b) the electrically conductive printed track may have a second thermal conductiveness C₂, a second thermal conductivity k₂, and a track thickness (tₜ), wherein C₂=k₂*tₜ; (c) the extended printed region may have a third thermal conductiveness C₃, a third thermal conductivity k₃, and a region thickness (tᵣ), wherein C₃=k₃*tᵣ; and (d) C₃/C₂≥1, C₁/C₂≥2, and C₁/C₃≥2.

Such embodiments may be beneficial as the printed tracks may remain relatively narrow, i.e., using as little printing material as possible, while a desired thermal performance may still be achieved through the addition of a relatively cheap thermally conductive layer with a thermal conductiveness higher than the printed tracks. Hence, in embodiments, an electronics arrangement with an improved price-performance ratio may be provided.

In embodiments, the electrically conductive printed track and the extended printed region may, comprise essentially the same material. Hence, the electrically conductive printed track material and the extended printed region material may be essentially the same material. Therefore, in embodiments, the second thermal conductivity k₂ and the third thermal conductivity k₃ may be substantially equal, i.e., k₁=k₂. However, in embodiments, the second thermal conductivity and the third thermal conductivity may also be (slightly) different. In such embodiments especially, the following may apply: 0.5≤k₂/k₃≤2, such as 0.75≤k₂/k₃≤1.5.

Further, in embodiments, the electrically conductive printed track and the extended printed region may, have essentially the same thickness. Therefore, in embodiments, the track thickness (tₜ) and the region thickness (tᵣ) may be substantially equal, i.e., tᵣ=tᵣ. However, in embodiments, the region thickness (tᵣ) may also be (slightly) larger than the track thickness (tₜ), i.e. tᵣ≥tₜ. In such embodiments especially, tᵣ/tₜ≥1.05, such as tᵣ/tₜ≥1.1, like tᵣ/tₜ≥1.2.

In embodiments, the thermal conductiveness of the electrically conductive printed track and the extended printed region may thus be essentially equal, i.e., C₃/C₂=1. In other embodiments, the thermal conductiveness of the extended printed region may be slightly higher than the thermal conductiveness of the electrically conductive printed track, i.e., C₃/C₂≥1.1, such as C₃/C₂≥1.5, like C₃/C₂≥2.

Further, in embodiments, the thermally conductive layer material may especially have a first thermal conductivity k₁ selected from the range of ≥30 W/mK, such as from the range of 30-100 W/mK, like from the range of 40-80 W/mK. Instead of “W/m*K” also the indications W/mK or W·m−1·K−1 may be applied. Yet further, in embodiments, the thermally conductive layer material may have a layer thickness selected from the range of 10-500 μm, see also further below. Hence, especially, in embodiments, the thermally conductive layer may have a higher thermal conductiveness (C=k*t) than the electrically conductive printed track material and the extended printed region material. Especially, in embodiments, C₁/C₂≥1, such as C₁/C₂≥1.5, like C₁/C₂≥2, especially C₁/C₂≥5. Similarly, in embodiments, C₁/C₃≥1, such as C₁/C₃≥1.5, like C₁/C₃≥2, especially C₁/C₃≥5. Especially, in embodiments, the first thermal conductiveness C₁ may be selected from the range of C₁≥0.001 W/K, such as C₁≥0.002 W/K, like C₁≥0.004 W/K. Hence, in specific embodiments, the thermally conductive layer may have a thermal conductiveness C₁ selected from the range of ≥0.001 W/K. Further, in embodiments, the second thermal conductiveness (of the electrically conductive printed track) C₂ may be selected from the range of 0.0002-0.02 W/K, such as from the range of 0.002-0.01 W/K. Likewise, in embodiments, the third thermal conductiveness (of the extended printed region) C₃ may be selected from the range of 0.0002-0.04 W/K, such as from the range of 0.004-0.02 W/K.

As mentioned above, the thermally conductive layer may comprise the thermally conductive layer material. Especially, in specific embodiments, the thermally conductive layer material may comprise one or more of the group comprising lead, tin, silver, copper, zinc, bismuth, indium, antimony, phosphorous, cadmium, nickel, gold and germanium. In particular, the thermally conductive layer material may comprise one or more electrically conductive elements, such as transition metals. Hence, in specific embodiments, the thermally conductive layer material may comprise one or more of the group comprising lead, tin, silver, copper, zinc, bismuth, indium, antimony, phosphorous, cadmium, nickel, gold, and germanium. In some embodiments, the thermally conductive layer material may comprise a pure material. However, the thermally conductive layer material may especially, in embodiments, comprise a combination of one or more (metal) materials, i.e., an alloy. For example, in embodiments, the thermally conductive layer material may comprise a solder. In specific embodiments, the thermally conductive layer may comprise a low-temperature solder. Low-temperature solders (or “soft solders”) may commonly refer to lead-based solders, such as Sn—Pb, or lead-free solders, such as Sn—Ag—Cu. Low-temperature solders may especially comprise solders having a melting point temperature in the range of 90-450° C. In embodiments, low-temperature solders may especially be selected in combination with a flexible support board, such as a flexible printed circuit board. In other embodiments, the thermally conductive layer may comprise a high-temperature (or “hard”) solder. High-temperature solders may commonly refer to alloys of copper with zinc and/or silver. High-temperature solders may especially comprise solders having a melting point temperature above 450° C. In embodiments, high-temperature solders may especially be selected in combination with a support board with a high thermal stability, such as an aluminum support board.

The thermally conductive layer may thus comprise a material selected according to the desired thermal properties. Further, in embodiments, the thermally conductive layer may be configured such that the thermal management may be improved. Especially, the thermally conductive layer may be configured in a segmented pattern. The segmented pattern may especially comprise n segments configured at least partly around the electronic element. Herein, in embodiments, n may especially be selected from the range of 2≤n≤50, such as 2≤n≤30, such as from the range of 4≤n≤20, like from the range of 5≤n≤15. The n segments may, in embodiments, each comprise the thermally conductive layer material. Further, in embodiments, the n segments may at least partially be separated by channels not comprising the thermally conductive layer material. Especially, each segment may, in embodiments, comprise a segment area Aᵢ. More especially, the cross-sectional area A_{T} of the extended printed region may, in embodiments, comprise the segment areas Aᵢ of the n segments together, i.e.,

$${\sum }_{i = 1}^{n} {A}_{i} \leq {A}_{T} .$$

Further, in embodiments, the channels may have a width (d) selected from the range of 100-1000 μm, such as from the range of 100-500 μm. Hence, in specific embodiments, the thermally conductive layer may be configured in a segmented pattern, wherein the segmented pattern may comprise n segments configured at least partly around the electronic element, wherein the n segments, each comprising the thermally conductive layer material, may at least partially be separated by channels not comprising the thermally conductive layer material, wherein 2≤n≤20, wherein each segment may comprise a segment area Aᵢ, wherein

$${\sum }_{i = 1}^{n} {A}_{i} \leq {A}_{T} .$$

and wherein the channels may have a width (d) selected from the range of 50-1000 μm. The channel width may in embodiments essentially constant over the channel length(s). In other embodiments, however, the channel widths may vary over the channel length(s).

In embodiments, the thermally conductive layer may be configured as a uniform layer (n=1). However, in other embodiments, the thermally conductive layer may (also) be configured in a pattern. Especially, in such embodiments, the thermally conductive layer may be configured in a segmented pattern, i.e., the electronics arrangement may comprise segments of thermally conductive layer. In embodiments the segmented pattern of the thermally conductive layer may comprise n segments (n≥2). Especially, the n segments may each comprise the thermally conductive layer material.

In embodiments, the n segments of the segmented pattern may be configured at least partly around the electronic element. In other words, the n segments of the segmented pattern may be configured to partly surround the electronic element. In embodiments, the n segments may be configured to surround at least 50% of the electronic element, such as at least 60%, like at least 70%, especially at least 80% of the electronic element. In some embodiments, the n segments may be configured around the electronic element such that the electronic element may be fully surrounded (i.e., 100% surrounded) by, and that the electronic element may be centered in the segmented pattern.

The n segments may, in embodiments, comprise segments of substantially equal size and shape. However, in other embodiments the n segments may comprise segments having one or more of a different size and a different shape. In embodiments, the n segments may comprise concentric ring-like segments (, i.e., the n segments may have a different size but a similar shape). In other embodiments, the segmented pattern may comprise a fan-like pattern (, i.e., the n segments may comprise (different) 2D cone-like shapes configured in a fan-like pattern). Hence, in embodiments, the n segments may be separate segments having their own shape. The n segments may thus be at least partially separated. Especially, in embodiments, the n segments may be at least partially separated by channels not comprising the thermally conductive material. In embodiments, the n segments may be fully separated by channels not comprising the thermally conductive material.

In embodiments, the channels (not comprising the thermally conductive material) may have a width (d) (defined in a plane parallel to the first face of the support board). Especially, the (channel) width (d) may be selected from the range of 10-1000 μm, such as from the range of 50-1000 μm, like from the range of 200-500 μm. In some embodiments, the channels may all have a substantially equal width (d). However, in other embodiments, the channels may have different widths (d) selected from the range described above. A too large width (d) may, in embodiments, inhibit the thermal conductivity between the n segments of thermally conductive material. On the other hand, in embodiments, a narrow but non-zero width (d), may be difficult to achieve during manufacturing of the electronics arrangement. Thus, in this way it improves the reliability of the electronics arrangement.

As mentioned above, in embodiments, the n segments may be at least partially separated by channels not comprising the thermally conductive material. In some embodiments, the n segments may not be fully separated by the channels. Especially, in such embodiments, at least some of the n segments may be connected. More especially, at least a set of two segments may be connected via one or more tracks. The one or more tracks may, in embodiments, be configured within the channels. Further, the one or more tracks may be configured between the two segments (of the set). Hence, in specific embodiments, at least a set of two segments may be connected via one or more tracks configured within the channel configured between the two segments.

In embodiments, the electronics arrangement may comprise n≥2 segments of thermally conductive layer material. In embodiments, a set of two segments may be (largely) separated by a channel not comprising the thermally conductive layer material. In some embodiments, especially, the set of two segments may not be fully separated by the channel, i.e., the set of two segments may be connected. Especially, in such embodiments, the set of two segments may be connected via one or more tracks. Such tracks may, in embodiments, comprise the thermally conductive layer material. Hence, in embodiments, the set of two segments may be connected via one or more (such as two, relatively small) tracks configured within the channel configured between the two segments (to largely separate the two segments). The segmented pattern may, in embodiments, comprise one or more of such sets of two segments connected via one or more tracks. For example, in embodiments, n=6 and the segmented pattern may comprise three sets of each two segments connected via one or more tracks.

Further, in embodiments, one of the n segments may be connected to more than one other segment. For example, in embodiments, one of the n segments may be connected to two neighboring segments. In other embodiments, the segmented pattern may comprise one segment surrounded by three (or more) other segments. In such embodiments, for example, the one segment may be connected to the three (or more) other segments, such that a fan symbol-like shape is formed.

The use of segments may be beneficial during production. A single large segment may complicate positioning of the electrical element. When using segments, this may be more easy, as a possible displacement of the electrical element may be reduced or prevented. Thus, in this way it improves the reliability of the electronics arrangement.

In embodiments, the segmented pattern as described here (i.e., the n segments together) may (also) have a defined shape. The shape may especially be dependent on the shape of the extended printed region on which the thermally conductive layer may be configured. Especially, in embodiments, the extended printed region may have a horse-shoe like shape defined parallel to the (first face of the) support board. More especially, the extended printed region may be at least partly configured around the electronic element. In such embodiments, especially, the electrically conductive printed track material and the extended printed region material may be the same materials. Further, in such embodiments, the thermally conductive layer cross-sectional area (A_{S}) may be larger than the electronic element cross-sectional area (A_{E}), i.e., 2.5≤A_{S}/A_{E}≤20, such as 2.5≤A_{S}/A_{E}≤10, like 4≤A_{S}/A_{E}≤8. Hence, in specific embodiments, the extended printed region may have a horse-shoe like shape, defined parallel to the support board, and may be at least partly configured around the electronic element; wherein 2.5≤A_{S}/A_{E}≤10; and wherein the electrically conductive printed track material and the extended printed region material may be the same materials. In embodiments, the extended printed region may have a shape approximating one of a rectangular shape, a circular shape, an oval shape, a polygonal shape, an amorphous shape, a u-shape, and a horse-shoe like shape (defined parallel to the first face of the support board), such as especially a u-shape, or especially a horse-shoe like shape.

The term “approximate” and its conjugations herein, such as in “to approximate a shape”, refers to being nearly identical to, especially identical to, the following term, for example nearly identical to a circular shape or a polygonal shape. For example, the extended printed region may define an oval shape but for a defect. Similarly, for example, a circular shape defined by the extended printed region may not be perfectly round but slightly ovoid. In particular, an object approximating a first shape may herein refer to: a first shape realization encompassing the object, wherein the first shape realization is defined as the smallest encompassing shape of the (2D or 3D, respectively) object wherein the first shape realization has the shape of the first shape, wherein a ratio of the area (volume) of the first shape realization to the area (volume) of the object is ≤1.2, especially ≤1.1, such as ≤1.05, especially ≤1.02. For instance, the extended printed region may approximate a horse-shoe shape, wherein the first shape realization may be defined as the smallest encompassing horse-shoe shape of the extended printed region, wherein a ratio of the volume of the first shape realization to the volume of the extended printed region is ≤1.2, especially, especially ≤1.1, such as ≤1.05, especially ≤1.02, including 1. Further, if the dimensions of the first shape are defined, the term approximate may refer to the object and the first shape being superimposable (in 2D or 3D, respectively) such that an intersection between the object and the first shape covers at least n % of the object and at least n % of the shape, wherein n is at least 90%, such as at least 95%, especially at least 98%, such as at least 99%, including 100%.

The extended printed region may especially, in embodiments, be at least partly configured around the electronic element. Hence, the (shape of the) extended printed region (defined parallel to the first face of the support board) may at least partly surround the electronic element. In embodiments, the (shape of the) extended printed region (defined parallel to the first face of the support board) may (even) essentially fully surround the electronic element. For example, in embodiments where the extended printed region may have a horse-shoe like shape, the electronic element may be configured within the horse-shoe like shape. Such a horse-shoe like shape may provide a beneficial trade-off between effectiveness of the thermal management of the arrangement and the cost of material. Hence, in such embodiments, the extended printed region may be configured partly around the electronic element. Likewise, in another example where the extended printed region may have an oval shape, in embodiments, the electronic element may be configured centered in the oval shape. Hence, in such embodiments, the extended printed region may be configured essentially fully around the electronic element.

In particular, the shape of the extended printed region may be chosen and the thermally conductive layer may be configured such, that a heat generating component of the electronic element may be configured in thermal contact with the thermally conductive layer. For example, in embodiments where the electronic element has an anode and a heat generating cathode, the extended printed region and the thermally conductive layer may have a horse-shoe like shape only partially surrounding the electronic element, such that thermal management for the heat generating cathode may be provided. In another example, in embodiments where the electronic element has a heat generating anode and a heat generating cathode, the extended printed region and the thermally conductive layer may have a e.g. an oval shape fully surrounding the electronic element, such that thermal management for both the heat generating anode and the heat generating cathode may be provided. In some embodiments, the electronic element may also have an anode and a cathode for the electrical connection of the electronic element, and a heat slug configured for thermal management of the electronic element.

At least part of the extended printed region may be covered by the thermally conductive layer. Hence, as mentioned above, the electronic element cross-sectional area (A_{E}) may be correlated to the thermally conductive layer cross-sectional area (A_{S}). Especially, in embodiments where the extended printed region may have a horse-shoe like shape, 2.5≤A_{S}/A_{E}≤10. Hence, in such embodiments, the thermally conductive layer cross-sectional area (A_{S}) may be at least two and a half times larger than the electronic element cross-sectional area, such as at least three times larger, like at least five times larger. Further, in such embodiments, the electrically conductive printed track material and the extended printed region material may especially be the same materials.

In further embodiments, the thermally conductive layer may have a thickness (tₛ) defined perpendicular to the layer cross-sectional area (A_{S}). Especially, the thermally conductive layer thickness (tₛ) may be an average thickness. The thermally conductive layer thickness (tₛ) may especially be selected from the range of 10-500 μm. Likewise, in embodiments, the electrically conductive printed track may have a thickness (tₜ) defined perpendicular to the support board. The electrically conductive printed track thickness (tₜ) may especially be selected from the range of 5-50 μm. Hence, in specific embodiments, the thermally conductive layer may have a thickness (tₛ) selected from the range of 10-500 μm; and wherein the electrically conductive printed track may have a thickness (tₜ) selected from the range of 5-50 μm.

Herein, the thermally conductive layer thickness (tₛ) may refer to an average thickness. Hence, the values described for the thermally conductive layer thickness (tₛ) may represent an average thickness over the whole layer cross-sectional area (A_{S}). The thickness is herein described as an average thickness as the thermally conductive layer may not be consistent in thickness. Especially, the thermally conductive layer may, in embodiments, slope down or curve at its boundaries, similar to a droplet. Furthermore, in embodiments, the thermally conductive layer may overlay elements of different height, which may cause a relief texture with variations in the thermally conductive layer thickness. In particular, such variations may exist as the thermally conductive layer thickness may be defined perpendicular to layer cross-sectional area (A_{S}). Yet further, in embodiments, the thermally conductive layer may comprise separate segments, such as described above. In such embodiments, the separate segments may each have the same (average) thickness (tₛ). However, in other such embodiments, the separate segments may also differ in (average) thickness (tₛ). Hence, in embodiments, the thermally conductive layer may have a (n average) thickness (tₛ) selected from the range of 1-500 μm, such as from the range of 10-500 μm, like from the range of 20-100 μm.

Similarly to the thermally conductive layer, the electrically conductive printed track may (also) have an average thickness, i.e., a track thickness (tₜ). In embodiments, the track thickness (tₜ) may be defined perpendicular to the (first face of the) support board. Especially, in embodiments, track thickness (tₜ) may be selected from the range of 1-50 μm, such as from the range of 5-50 μm, like from the range of 15-35 μm. Likewise, in embodiments, the extended printed region may have an average thickness, i.e., a region thickness (tᵣ). In embodiments, the region thickness (tᵣ) may be defined perpendicular to the (first face of the) support board. Especially, in embodiments, region thickness (tᵣ) may be selected from the range of 1-50 μm, such as from the range of 5-50 μm, like from the range of 15-35 μm.

As mentioned above, the electrically conductive printed track may comprise an electrically conductive printed track material comprising additional electrically conductive particles. Hence, in embodiments, the electrically conductive printed track material may comprise electrically conductive particles. Likewise, in embodiments, the extended printed region material may comprise electrically conductive particles. Such electrically conductive particles may comprise an electrically conductive material. Especially, the electrically conductive particles may, in embodiments, comprise one or more of Ag, Cu, Au, and Al. Furthermore, the electrically conductive particles may have a spherical equivalent diameter selected from the range of 1-15 μm. Hence, in specific embodiments, the electrically conductive printed track material may comprise electrically conductive particles, wherein the electrically conductive particles may comprise one or more of Ag, Cu, Au, and Al, and wherein the electrically conductive particles may have a spherical equivalent diameter selected from the range of 1-15 μm. The equivalent spherical diameter (or ESD) (or “spherical equivalent diameter”) of an (irregularly shaped) three-dimensional shape is the diameter of a sphere of equivalent volume. For instance, the equivalent spherical diameter of a cube with side a is SQRT[3]((6*a\hat{ }3)/π). For a sphere, the diameter is the same as the equivalent spherical diameter. Would a sphere in an xyz-coordinate system with a diameter D be distorted to any other shape (in the xyz-coordinate system), without changing the volume size, then the equivalent spherical diameter of that shape would be D.

In embodiments, the electrically conductive particles may have a spherical shape. In other embodiments, the electrically conductive particles may have another shape, such as a disc(-like) shape, a rod(-like) shape, or an ovoid(-like) shape. Therefore, in embodiments, the electrically conductive particles may be defined by their spherical equivalent diameter. In embodiments, the electrically conductive particles may be nano- and/or microparticles. Hence, the spherical equivalent diameter of the electrically conductive particles may be selected from the range of 50-1000 nm, such as from the range of 100-1000 nm, like at least 500 nm. Especially, in embodiments, the spherical equivalent diameter of the electrically conductive particles may be selected from the range of 1-15 μm, such as from the range of 1-10 μm, like from the range of 5-10 μm.

Further, in embodiments, the electrically conductive particles may be substantially equal in shape, size and material. In other embodiments, one or more of shape, size, and material of the electrically conductive particles may vary. For example, in embodiments, the extended printed region material may comprise both silver (Ag) particles and copper (Cu) particles.

Yet further, in embodiments, the electrically conductive printed track material and/or the extended printed region material may comprise a matrix material. Especially, in embodiments, the electrically conductive particles may be added to the matrix material to form a conductive polymer composite. In embodiments, the matrix material may, for example, comprise a polymeric material, such as the polymeric materials described further above (e.g. polyaniline or polypyrrole).

As mentioned above, the electronic element may, in embodiments, comprise a light emitting diode (LED). Especially, in embodiments, the electronic element may comprise a solid state light source. More especially, in embodiments, the solid state light source may comprise one or more of a LED, a UV LED, and an IR LED. Such a solid state light source may also, in embodiments, comprise a superluminescent diode, or a laser diode (see also further below). The solid state light source may, in embodiments, be electrically connected to the electrically conductive printed track. Especially, the solid state light source may be connected such, that the solid state light source may be configured to generate light source light.

In embodiments, the electronics arrangement may comprise one or more extended printed regions. Especially, the electronics arrangement may comprise m extended printed regions. More especially, m≥1, such as m≥5, like m≥10. Further, in embodiments, the electronics arrangement may comprise one or more electronic elements. Especially, the electronics arrangement may comprise p electronic elements. More especially, p≥1 such as p≥5, like p≥10. In embodiments, the p electronic elements may be electrically coupled via the electrically conductive printed track. Hence, in embodiments, one or more parts of the electrically conductive printed track may be (partially) surrounded by a local extended printed region. Especially, in embodiments m=p. However, this may not necessarily be the case. Furthermore, in specific embodiments, at least one of the p electronic elements may comprise the (solid-state) light source as described above.

Hence, in another aspect, the invention may provide a light generating system comprising the electronics arrangement as described above. Further, in embodiments, the light generating system may comprise a light generating device. The light generating device may be configured to generate device light. Further, in embodiments, the light generating device may comprise the solid state light source. The solid state light source may, in embodiments, comprise a first contact and a second contact. Especially, in embodiments, the first contact may be a cathode contact and the second contact may be an anode contact. In embodiments, the first contact may be configured in thermal contact with the thermally conductive layer and in electrical contact with a first electrically conductive printed track. Further, in such embodiments, the second contact may be configured in electrical contact with a second electrically conductive printed track. Hence, in specific embodiments, the light generating system may comprise a light generating device configured to generate device light, wherein the light generating device may comprise the solid state light source; wherein the solid state light source may comprise a first contact and a second contact, wherein the first contact may be configured in thermal contact with the thermally conductive layer and in electrical contact with a first electrically conductive printed track, wherein the second contact may be configured in electrical contact with a second electrically conductive printed track.

In embodiments, the light generating system may comprise the electronics arrangement as described above and a light generating device. Additionally, in embodiments, the light generating system may comprise one or more of optical elements (e.g. a lens, a reflector etc, etc.), a sensor, and a control system.

As indicated above, the light generating system may comprise a light generating device. A light generating device may especially be configured to generate device light. In embodiments, the light generating device may be configured to generate visible device light. In specific embodiments, the light generating device may be configured to generate white device light. Especially, the light generating device may comprise the light source. The light source may especially configured to generate light source light. In embodiments, the device light may essentially consist of the device light. In other embodiments, the device light may essentially consist of converted light source light. In yet other embodiments, the device light may comprise (unconverted) light source light and converted light source light. Light source light may be converted with a luminescent material into luminescent material light and/or with an upconverter into upconverted light (see also below). The term “light generating device” may also refer to a plurality of light generating devices which may provide device light having essentially the same spectral power distributions. In specific embodiments, the term “light generating device” may also refer to a plurality of light generating devices which may provide device light having different spectral power distributions.

The term “light source” may in principle relate to any light source known in the art. It may be a conventional (tungsten) light bulb, a low pressure mercury lamp, a high pressure mercury lamp, a fluorescent lamp, an LED (light emissive diode). In a specific embodiment, the light source comprises a solid state LED light source (such as an LED or laser diode (or “diode laser”)). The term “light source” may also relate to a plurality of light sources, such as 2-2000 (solid state) LED light sources. Hence, the term LED may also refer to a plurality of LEDs. Further, the term “light source” may in embodiments also refer to a so-called chips-on-board (COB) light source. The term “COB” especially refers to LED chips in the form of a semiconductor chip that is neither encased nor connected but directly mounted onto a substrate, such as a PCB. Hence, a plurality of light emitting semiconductor light source may be configured on the same substrate. In embodiments, a COB is a multi LED chip configured together as a single lighting module. The term “light source” may refer to a semiconductor light-emitting device, such as a light emitting diode (LEDs), a resonant cavity light emitting diode (RCLED), a vertical cavity laser diode (VCSELs), an edge emitting laser, etc., The term “light source” may also refer to an organic light-emitting diode (OLED), such as a passive-matrix (PMOLED) or an active-matrix (AMOLED). In a specific embodiment, the light source comprises a solid-state light source (such as an LED or laser diode). In an embodiment, the light source comprises an LED (light emitting diode). The terms “light source” or “solid state light source” may also refer to a superluminescent diode (SLED). The term LED may also refer to a plurality of LEDs.

In embodiments, the light source may comprise one or more micro-optical elements (array of micro lenses) downstream of a single solid-state light source, such as an LED, or downstream of a plurality of solid-state light sources (i.e. e.g. shared by multiple LEDs). In embodiments, the light source may comprise an LED with on-chip optics. In embodiments, the light source comprises pixelated single LEDs (with or without optics) (offering in embodiments on-chip beam steering). In embodiments, the light source may be configured to provide primary radiation, which is used as such, such as e.g. a blue light source, like a blue LED, or a green light source, such as a green LED, and a red light source, such as a red LED. Such LEDs, which may not comprise a luminescent material (“phosphor”) may be indicated as direct color LEDs.

The term “light source” may (thus) refer to a light generating element as such, like e.g. a solid state light source, or e.g. to a package of the light generating element, such as a solid state light source, and one or more of a luminescent material comprising element and (other) optics, like a lens, a collimator. A light converter element (“converter element” or “converter”) may comprise a luminescent material comprising element. For instance, a solid state light source as such, like a blue LED, is a light source. A combination of a solid state light source (as light generating element) and a light converter element, such as a blue LED and a light converter element, optically coupled to the solid state light source, may also be a light source (but may also be indicated as light generating device). Hence, a white LED is a light source (but may e.g. also be indicated as (white) light generating device).

The term “light source” may (thus) in embodiments also refer to a light source that is (also) based on conversion of light, such as a light source in combination with a luminescent converter material. Hence, the term “light source” may also refer to a combination of an LED with a luminescent material configured to convert at least part of the LED radiation, or to a combination of a (diode) laser with a luminescent material configured to convert at least part of the (diode) laser radiation. In embodiments, the term “light source” may also refer to a combination of a light source, like an LED, and an optical filter, which may change the spectral power distribution of the light generated by the light source. Especially, the term “light generating device” may be used to address a light source and further (optical components), like an optical filter and/or a beam shaping element, etc. The phrases “different light sources” or “a plurality of different light sources”, and similar phrases, may in embodiments refer to a plurality of solid-state light sources selected from at least two different bins. Likewise, the phrases “identical light sources” or “a plurality of same light sources”, and similar phrases, may in embodiments refer to a plurality of solid-state light sources selected from the same bin. The term “solid state light source”, or “solid state material light source”, and similar terms, may especially refer to semiconductor light sources, such as a light emitting diode (LED), a diode laser, or a superluminescent diode.

In embodiments, the solid state light source may comprise a first contact and a second contact. Especially, in embodiments, the first contact may be a cathode contact and the second contact may be an anode contact. The anode contact and the cathode contact may, in embodiments, be electrically coupled to the electronics arrangement.

Solid state light sources may generate heat. Accumulation of heat may be detrimental to the performance of the solid state light sources. Therefore, in embodiments, the first and/or second contact may be thermally coupled to the thermally conductive layer. Furthermore, in embodiments, the solid state light source may also comprise an additional heat slug configured to dissipate heat away from the solid state light source. Especially, the heat slug may be configured in thermal contact with the thermally conductive layer. Hence, in embodiments, the thermally conductive layer may be configured as a heat spreader for the solid state light source.

Further, in embodiments, the light generating system may comprise the extended printed region having the horse-shoe like shape as described above. In such embodiments, the cross-sectional area (A_{T}) of the extended printed region may be selected from the range of 2-1000 mm², such as from the range of 5-800 mm², like from the range of 10-400 mm², especially from the range of 50-200 mm². Hence, in specific embodiments, the light generating system may comprise the extended printed region, wherein the extended printed region may have the horse-shoe like shape as defined above, and wherein the cross-sectional area (A_{T}) of the extended printed region may be selected from the range of 4-1000 mm².

Such embodiments may be beneficial as the horse-shoe like shape may facilitate improved heat dissipation from the light source, which may in turn increase the lifetime of the light source.

Yet further, in embodiments, the light generating system may comprise the thermally conductive layer. In such embodiments, the thermally conductive layer may comprise the segmented pattern as described above. Especially, the channels (in the segmented pattern) may have a total channel area (A_{TC}). In embodiments, the total channel area (A_{TC}) may be small relative to the extended printed region cross-sectional area (A_{T}), i.e., 0.001≤A_{TC}/A_{T}≤0.5, such as 0.005≤A_{TC}/A_{T}≤0.1, like 0.005≤A_{TC}/A_{T}≤0.08. Furthermore, in embodiments, the channels may have a total channel length (L_{TC}). Especially, the total channel length (L_{TC}) may be at least 0.5*√(A_{TC}/π), such as at least 0.7*√(A_{TC}/π), like at least 0.9*√(A_{TC}/π). Hence, in specific embodiments, the light generating system may comprise the thermally conductive layer, wherein the thermally conductive layer may comprise the segmented pattern as defined above, wherein the channels may have a total channel area (A_{TC}), wherein 0.001≤A_{TC}/A_{T}≤0.5, and wherein the channels may have a total channel length (L_{TC}) of at least 0.5*√(A_{TC}/π).

The light generating system may be part of or may be applied in e.g. office lighting systems, household application systems, shop lighting systems, home lighting systems, accent lighting systems, spot lighting systems, theater lighting systems, fiber-optics application systems, projection systems, self-lit display systems, pixelated display systems, segmented display systems, warning sign systems, medical lighting application systems, indicator sign systems, decorative lighting systems, portable systems, automotive applications, (outdoor) road lighting systems, urban lighting systems, green house lighting systems, horticulture lighting, digital projection, or LCD backlighting. The light generating system (or luminaire) may be part of or may be applied in e.g. optical communication systems or disinfection systems.

In yet a further aspect, the invention also provides a lamp or a luminaire comprising the light generating system as defined herein. The luminaire may further comprise a housing, optical elements, louvres, etc. etc. . . . The lamp or luminaire may further comprise a housing enclosing the light generating system. The lamp or luminaire may comprise a light window in the housing or a housing opening, through which the system light may escape from the housing. In yet a further aspect, the invention also provides a projection device comprising the light generating system as defined herein. Especially, a projection device or “projector” or “image projector” may be an optical device that projects an image (or moving images) onto a surface, such as e.g. a projection screen. The projection device may include one or more light generating systems such as described herein. Hence, in an aspect the invention also provides a lighting device selected from the group of a lamp, a luminaire, a projector device, a disinfection device, a photochemical reactor, an automotive lighting device, and an optical wireless communication device, comprising the light generating system as defined herein, wherein the light generating device may be selected from the group of a laser, a LED, a superluminescent diode, a semiconductor chip, and a COB. The lighting device may comprise a housing or a carrier, configured to house or support, one or more elements of the light generating system. For instance, in embodiments the lighting device may comprise a housing or a carrier, configured to house or support the electronics arrangement.

In a yet further aspect, the invention may provide a method of manufacturing the electronics arrangement (as described above). The method may especially, in embodiments, comprise a printing stage, a layering stage, an assembly stage, and a curing stage. During the printing stage, in embodiments, electrically conductive printed tracks, and an extended printed region may be printed onto a support board. Herein, the extended printed region may especially comprise an extended printed region cross-sectional area (A_{T}) defined parallel to (a first face of) the support board. Further, in embodiments, the extended printed region may comprise an extended printed region material. Yet further, in embodiments, the electrically conductive printed tracks may comprise an electrically conductive printed track material. In embodiments, during the layering stage, a layer mask may be applied over at least part of the extended printed region. Subsequently, in embodiments, a thermally conductive layer precursor material may be applied over the layer mask. After removal of the layer mask, during an assembly stage, an electronic element may, in embodiments, be configured on the support board. The electronics element may especially, in embodiments, comprise a first contact and a second contact. In embodiments, the electronics element may be (a) configured with its first contact in thermal contact with the thermally conductive layer precursor material and in electrical contact with a first electrically conductive printed track, and (b) configured with its second contact in electrical contact with a second electrically conductive printed track. In particular, the electronic element may be configured as such to provide an assembly. Further, in embodiments, the electronic element may have an electronic element cross-sectional area (A_{E}) defined parallel to the (first face of the) support board. In embodiments, during the curing stage the thermally conductive layer precursor material may be heated to provide a thermally conductive layer. Especially, the thermally conductive layer may comprise a thermally conductive layer material. More especially, the thermally conductive layer may, in embodiments, comprise a layer cross-sectional area (A_{S}) defined parallel to (the first face of) the support board. In embodiments, the printing stage may be executed such and the layer mask may be chosen such that a ratio A_{S}/A_{T} of at most 1.1 may be obtained, such as a ratio of at least 0.9, including a ratio of 1. Hence, in specific embodiments, the invention may provide a method of manufacturing an electronics arrangement, comprising: (i) a printing stage, wherein electrically conductive printed tracks, and an extended printed region, may be printed onto a support board; wherein the extended printed region may comprise a cross-sectional area (A_{T}) defined parallel to the support board; (ii) a layering stage, wherein a layer mask may be applied over at least part of the extended printed region; wherein a thermally conductive layer precursor material may be applied over the layer mask; (iii) an assembly stage, wherein, after removal of the layer mask, an electronic element, comprising a first contact and a second contact, may be (a) configured with its first contact in thermal contact with thermally conductive paste and in electrical contact with a first electrically conductive printed track, and (b) configured with its second contact in electrical contact with a second electrically conductive printed track; wherein the electronic element may have a cross-sectional area (A_{E}) defined parallel to the support board; and (iv) a curing stage, wherein the thermally conductive layer precursor material may be heated to provide a thermally conductive layer; wherein the thermally conductive layer may comprise a cross-sectional area (A_{S}) defined parallel to the support board; wherein the printing stage is executed such and the layer mask may be chosen such that a ratio A_{S}/A_{T} of at most 1.1 is obtained.

In embodiments, the printing stage may comprise printing an electrically conductive printed track material and an extended printed region material onto the support board, such that an electrically conductive printed track and an extended printed region may be obtained. The electrically conductive printed track material and the extended printed region material have been described above. Especially, in embodiments, the electrically conductive printed track material and the extended printed region material may be essentially the same material.

In embodiments of the method, the electrically conductive printed track material (and the extending printed region material) may be selected such, that the electrically conductive printed track (and the extending printed region) may comprise electrically conductive particles. Herein especially, in embodiments, the electrically conductive particles may comprise one or more of Ag, Cu, Au, and Al. The electrically conductive particles have been further described above.

Further, in embodiments, the extended printed region material may be printed such, that an extended printed region with a cross-sectional area (A_{T}) defined parallel to (the first face of) the support board) may be obtained. The extended printed region cross-sectional area (A_{T}) has been further defined above in describing the electronics arrangement.

In embodiments, the layering stage may comprise applying a layer mask over at least part of the extended printed region. Especially, in embodiments, the layer mask may be configured essentially aligned with the extended printed region. Subsequently, in embodiments, the layering stage may comprise applying the thermally conductive layer precursor material over the layer mask. In embodiments, the thermally conductive layer precursor material may especially comprise a thermally conductive material. Especially, in specific embodiments, the thermally conductive layer precursor material may comprise one or more of lead, tin, silver, copper, zinc, bismuth, indium, antimony, phosphorous, cadmium, nickel, gold and germanium. In embodiments, the thermally conductive layer precursor material may comprise an alloy, such as a solder. Especially, in embodiments, the thermally conductive layer precursor material may comprise a thermally conductive paste.

Further, in embodiments, the method may comprise removing the layer mask after applying the thermally conductive layer precursor material.

After removal of the layer mask, in embodiments, the assembly stage may comprise configuring an electronic element comprising a first contact and a second contact. Especially, in embodiments, the assembly stage may comprise (a) configuring the first contact of the electrical element in thermal contact with the thermally conductive layer precursor material and in electrical contact with a first electrically conductive printed track, and (b) configuring the second contact of the electrical element in electrical contact with a second electrically conductive printed track. In such embodiments, the method may especially provide an assembly.

Embodiments of the electronic element have been further described above for the electronics arrangement and may also apply here. Especially, in embodiments, the electronic element may have an electronic element cross-sectional area (A_{E}) defined parallel to (the first face of) the support board. More especially, in embodiments, the electronic element cross-sectional area (A_{E}) may be selected from the range of 0.1-250 mm², such as from the range of 0.1-100 mm², like from the range of 1-10 mm².

In embodiments, the curing stage may comprise heating the thermally conductive layer precursor material such that a thermally conductive layer may be obtained. The thermally conductive layer may, in embodiments, especially have a thermal conductiveness (C1) selected from the range of ≥0.001 W/K.

Further, in embodiments, the thermally conductive layer obtained may comprise a cross-sectional area (A_{S}) defined parallel to (the first face of) the support board. Especially, the printing stage may be executed such and the layer mask may be chosen (and applied) such that a ratio A_{S}/A_{T} of at least 0.6 may be obtained, such as at least 0.8. More especially, the printing stage may be executed such and the layer mask may be chosen (and applied) such that a ratio A_{S}/A_{T} of at most 1.1 may be obtained, such as at most 1.

Further, in embodiments, the curing stage may comprise heating the thermally conductive layer precursor material. Especially, in embodiments, the thermally conductive layer precursor material may be heated to a temperature selected from the range of 120-400° C., such as selected from the range of 150-300° C. More especially, in such embodiments, the thermally conductive layer precursor material may be heated for a duration selected from the range of 5 seconds-60 minutes, such as selected from the range of 5-60 seconds, like selected from the range of 5-30 seconds, especially selected from the range of 10-60 minutes, such as from the range of 10-45 minutes.

Furthermore, in embodiments, the layering stage may be executed such and the electronic element may be selected such that the thermally conductive layer cross-sectional area (A_{S}) obtained may be larger than the electronic element cross-sectional area (A_{E}). Especially, in embodiments, 1.5≤A_{S}/A_{E}≤30. More especially, in embodiments, A_{S}/A_{E}≥1.5, such as A_{S}/A_{E}≥2.5, like A_{S}/A_{E}≥5. Hence, in specific embodiments, the curing stage may comprise heating thermally conductive layer precursor material to a temperature selected from the range of 120-400° C. for a duration selected from the range of 5 seconds-60 minutes; and wherein 1.5≤A_{S}/A_{E}≤30. Further, as described above, the layering stage may comprise applying the layer mask over at least part of the extended printed region. In embodiments, the layer mask may comprise a segmented mask pattern. Especially, the segmented mask pattern may comprise q mask cut-outs. More especially, in embodiments, 2≤q≤20, such as 2≤q≤12, like 5≤q≤10. In embodiments, the q mask cut-outs in the segmented mask pattern may be separated by mask channels. The mask channels may, in embodiments, have a mask channel width (d2). Especially, in embodiments, the mask channel width (d2) may be selected from the range of 50-1000 μm, such as from the range of 100-500 μm. Further, each mask cut-out may, in embodiments, comprise a cut-out area (A_{J}). Especially, in embodiments, the cut-out areas (A_{J}) of all q mask cut-outs together may be substantially equal to the extended printed region cross-sectional area (A_{T}) as defined above, i.e.,

$${\sum }_{j = 1}^{q} {A}_{j} = {A}_{T} .$$

The use of a layer mask with a segmented pattern may provide control over the distribution of the thermally conductive layer material. This may be beneficial, e.g. for following stages of the method of manufacturing. Especially, depositing a single segment of thermally conductive layer material and subsequently depositing the electronic element on top of the layer may cause sliding of the electronic element. On the other hand, depositing several separate segments of thermally conductive layer material and subsequently depositing the electronic element on top of the layer may result in poor thermal conductivity. Hence, the layer mask may be configured such, that the channels may provide a segmented thermally conductive layer, wherein the segments are sufficiently close to each other to provide relatively good thermal performance.

The method may further, in embodiments, comprise executing the curing stage such, that a thermally conductive layer with a(n) average layer thickness (tₛ) (defined perpendicular to the layer area (A_{S})) may be obtained. In embodiments, the (average) layer thickness (tₛ) may especially be selected from the range of 1-500 μm, such as from the range of 10-500 μm, like from the range of 20-100 μm.

Similarly, in embodiments, the method may comprise executing the printing stage such, that a thermally conductive printed track with a(n) average track thickness (tₜ) (defined perpendicular to (the first face of) the support board) may be obtained. In embodiments, the (average) track thickness (tₜ) may be selected from the range of 1-50 μm, such as from the range of 5-50 μm, like from the range of 15-35 μm.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1a-1d schematically depict some embodiments of the electronics arrangement described herein.

FIG. 2 schematically depicts a method of manufacturing the electronics arrangement.

FIG. 3 schematically depicts some applications of the electronics arrangement.

The schematic drawings are not necessarily to scale.

### DETAILED DESCRIPTION OF THE EMBODIMENTS

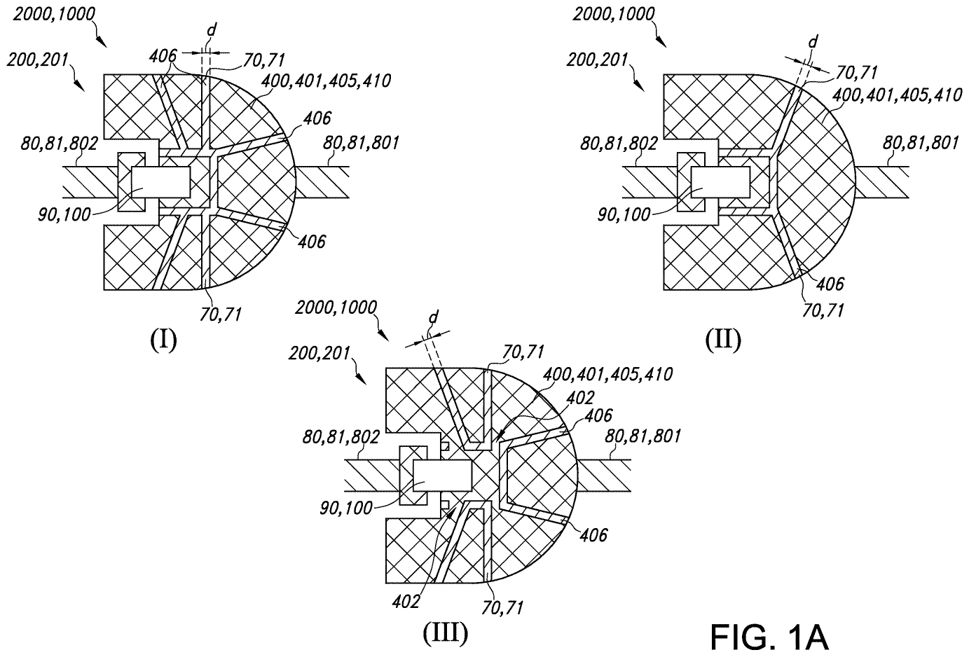

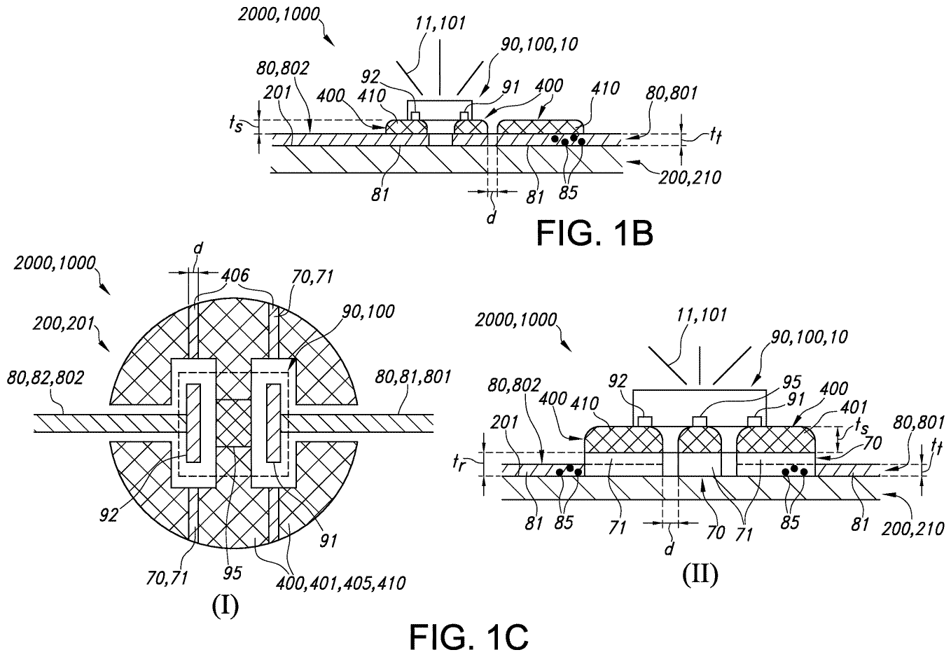

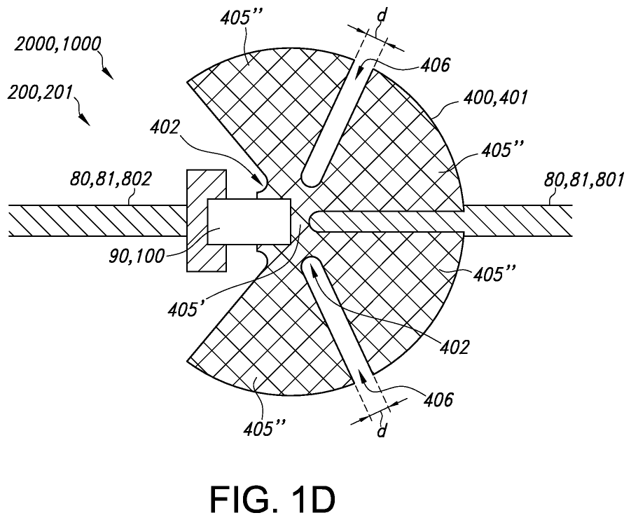

FIGS. 1a-1c schematically depict an electronics arrangement 2000 comprising a support board 200, an electrically conductive printed track 80, an extended printed region 70, an electronic element 90, and a thermally conductive layer 400. The support board 200 may especially be configured to support the electrically conductive printed track 80, the extended printed region 70, and the electronic element 90. Hence, the electrically conductive printed track 80, the extended printed region 70, and the electronic element 90 may be configured on (or “supported by”) the support board 200. More especially, the electrically conductive printed track 80 and the extended printed region 70 may be configured on a first face 201 of the support board 200.

In embodiments, the electrically conductive printed track 80 may comprise an electrically conductive printed track material 81. Likewise, in embodiments, the extended printed region 70 may comprise an extended printed region material 71.

The electronic element 90 may, in embodiments, be configured in electrical contact with the electrically conductive printed track 80. Especially, (an anode and a cathode of) the electronic element 90 may be configured such that a closed electrical circuit may be provided. Further, in embodiments, the electronic element 90 may comprise a cross-sectional area (A_{E}) defined parallel to the (first face 201 of the) support board 200. Yet further, in embodiments, the extended printed region 70 may comprise a cross-sectional area (A_{T}) defined parallel to the (first face 201 of the) support board 200. In embodiments, the extended printed region 70 may especially be configured in thermal contact with the electronic element 90. Optionally, the extended printed region 70 may also be configured in electrical contact with the electrically conductive printed track 80.

In embodiments, the thermally conductive layer 400 may at least partly be configured on (part of the electrically conductive printed track 80 and) at least part of the extended printed region 70. The thermally conductive layer 400 may especially comprise a thermally conductive layer material 410. More especially, in embodiments, the thermally conductive layer 400 may be in thermal contact with the electronic element 90. In embodiments, the thermally conductive layer 400 may comprise a cross-sectional area (A_{S}) defined parallel to the (first face 201 of the) support board 200. Especially, in embodiments, the thermally conductive layer 400 may be configured on the extended printed region 70, such that A_{S}/A_{T}≤1.1. More especially, in embodiments, the thermally conductive layer 400 may be configured on the extended printed region 70, such that A_{S}/A_{T}≥0.6. Further, in embodiments, the thermally conductive layer cross-sectional area A_{S} may be selected such, that 1.5≤A_{S}/A_{E}≤30. In yet further embodiments, A_{S}/A_{T}≤1.1, and 1.5≤A_{S}/A_{E}≤30.

In specific embodiments, the support board 200 may comprise a flexible printed circuit board.

Further, the thermally conductive layer 400 may have a first thermal conductiveness C₁, a first thermal conductivity k₁, and a layer thickness tₛ. Especially, in embodiments, C₁=k₁*tₛ. Similarly, in embodiments, the electrically conductive printed track 80 may have a second thermal conductiveness C₂, a second thermal conductivity k₂, and a track thickness tₜ. Especially, in embodiments, C₂=k₂*tₜ. Likewise, in embodiments, the extended printed region 70 may have a third thermal conductiveness C₃, a third thermal conductivity k₃, and a region thickness tᵣ. Especially, in embodiments, C₃-k₃*tᵣ. In embodiments, the track thickness tₜ and the region thickness tᵣ may be essentially equal, such as schematically depicted in FIG. 1B. However, in other embodiments, the track thickness tₜ and the region thickness tᵣ may be different, such as schematically depicted in FIG. 1C subfigure (II). Especially, in such embodiments, tᵣ≥tₜ. Further, in embodiments, one or more of the following may apply: C₃/C₂≥1, C₁/C₂≥2, and C₁/C₃≥2.

In specific embodiments, the (thermally conductive layer material 410 of) the thermally conductive layer 400 may have a thermal conductivity selected from the range of ≥0.001 W/K. Especially, the thermally conductive layer material 410 may comprise one or more of the group comprising lead, tin, silver, copper, zinc, bismuth, indium, antimony, phosphorous, cadmium, nickel, gold, and germanium. More especially, in embodiments, the thermally conductive layer 400 may comprise a low-temperature solder.

As depicted in FIG. 1A subfigure I and II, in embodiments, the thermally conductive layer 400 may be configured in a segmented pattern 401. The segmented pattern 401 may especially comprise n segments 405 configured at least partly around the electronic element 90. Herein, in embodiments, n may especially be selected from the range of 2≤n≤20. Especially, in subfigure I n=9, and in subfigure II n=5. The n segments 405 may, in embodiments, each comprise the thermally conductive layer material. Further, in embodiments such, the n segments 405 may at least partially be separated by channels 406 not comprising the thermally conductive layer material, such as depicted here in FIG. 1A. Especially, each segment 405 may, in embodiments, comprise a segment area (Aᵢ). More especially, the cross-sectional area (A_{T}) of the extended printed region 70 may, in embodiments, comprise the segment areas (Aᵢ) of the n segments 405 together, i.e.,

$${\sum }_{i = 1}^{n} {A}_{i} \leq {A}_{T} .$$

Further, in embodiments, the channels 406 may have a width d selected from the range of 50-1000 μm.

As mentioned above, in embodiments, the n segments 405 may be at least partially separated by channels 406 not comprising the thermally conductive material 410. In some embodiments, such as depicted in FIG. 1A subfigure III, the n segments 405 may not be fully separated by the channels 406. Especially, in such embodiments, at least some of the n segments 405 may be connected. More especially, at least a set of two segments 405 may be connected via one or more tracks 402. The one or more tracks 402 may, in embodiments, be configured within the channels 406. Further, the one or more tracks 402 may be configured between the two segments 405 (of the set).

In embodiments, the segmented pattern 401 as described here (i.e., the n segments 405 together,) may (also) have a defined shape. The shape may especially be dependent on the shape of the extended printed region 70 on which the thermally conductive layer 400 may be configured. Especially, in embodiments, the extended printed region 70 may have a horse-shoe like (or “u”-)shape defined parallel to the (first face 201 of the) support board 200, see FIG. 1A. In embodiments, not depicted here, the extended printed region 70 may also have a different shape, such as an oval-like shape. More especially, the extended printed region 70 may be at least partly configured around the electronic element 90. In such embodiments, especially, the electrically conductive printed track material 81 and the extended printed region material 71 may be the same materials. Further, in such embodiments, the thermally conductive layer cross-sectional area (A_{S}) may be larger than the electronic element cross-sectional area (A_{E}), i.e., 2.5≤A_{S}/A_{E}≤10.

In further embodiments, such as schematically depicted in FIG. 1B, the thermally conductive layer 400 may have a thickness tₛ defined perpendicular to the thermally conductive layer cross-sectional area (A_{S}). Especially, the thermally conductive layer thickness tₛ may be an average thickness. The thermally conductive layer thickness tₛ may especially be selected from the range of 10-500 μm. Likewise, in embodiments, the electrically conductive printed track 80 may have a thickness tₜ defined perpendicular to the support board 200. The electrically conductive printed track thickness tₜ may especially be selected from the range of 5-50 μm.

In embodiments, the electrically conductive printed track material 81 may comprise electrically conductive particles 85. Likewise, in embodiments, the extended printed region material 71 may comprise electrically conductive particles 85. Such electrically conductive particles 85 may comprise an electrically conductive material. Especially, the electrically conductive particles 85 may, in embodiments, comprise one or more of Ag, Cu, Au, and Al. Furthermore, the electrically conductive particles 85 may have a spherical equivalent diameter selected from the range of 1-15 μm (not depicted here).

Further, in embodiments, the electronic element 90 may comprise a solid state light source 10. Especially, the solid state light source 10 may be configured to provide light source light 11. Hence, in embodiments, the invention may provide a light generating system 1000 comprising the electronics arrangement 2000 as described above. Further, in such embodiments, the light generating system 1000 may comprise a light generating device 100. The light generating device 100 may be configured to generate device light 101. Further, in embodiments, the light generating device 100 may comprise the solid state light source 10. In embodiments, especially, the device light 101 may comprise the light source light 11. The solid state light source 10 may, in embodiments, comprise a first contact 91 and a second contact 92. Especially, in embodiments, the first contact 91 may be configured in thermal contact with the thermally conductive layer 400 and in electrical contact with a first electrically conductive printed track 801. In some embodiments, such as depicted here in FIG. 1B, the first contact 91 may be a cathode contact. Further, in embodiments, the second contact 92 may be configured in electrical contact with a second electrically conductive printed track 802. In some embodiments, such as depicted here in FIG. 1B, the second contact 92 may be an anode contact.

Further, in embodiments, the light generating system 1000 may comprise the extended printed region 70 having the horse-shoe like shape as described above. In such embodiments, the cross-sectional area (A_{T}) of the extended printed region 70 may be selected from the range of 4-1000 mm². However, in embodiments, the extended printed region 70 may also have a different shape, such as a shape approximating a circular shape or a polygonal shape. As depicted in FIG. 1C subfigure I, in embodiments, the extended printed region 70 may have an rounded shape (approximating a circle or an oval). Further, as depicted in FIG. 1C subfigure II, the extended printed region 70 and the electrically conductive printed track 80 may have a different thickness, i.e., tₜ≤tᵣ. However, in other embodiments, such as depicted in FIG. 1B, the extended printed region 70 and the electrically conductive printed track 80 may have a substantially equal thickness, i.e., tᵣ=tᵣ Yet further, as depicted in FIG. 1C, in embodiments, the electronic element may have a first contact 91, a second contact 92, and a third contact 95. In such embodiments, especially, the third contact 95 may comprise a heat slug.

Yet further, in embodiments, the light generating system 1000 may comprise the thermally conductive layer 400. In such embodiments, the thermally conductive layer 400 may comprise the segmented pattern 401 as described above. Especially, the channels 406 (in the segmented pattern 401) may have a total channel area (A_{TC}). In embodiments, the total channel area (A_{TC}) may be small relative to the extended printed region cross-sectional area (A_{T}), i.e., 0.001≤A_{TC}/A_{T}≤0.5. Furthermore, in embodiments, the channels 406 may have a total channel length (L_{TC}). Especially, the total channel length (L_{TC}) may be at least 0.5*√(A_{TC}/π). The total channel length (L_{TC}) may especially be an imaginary length of the channels 406 altogether, if all channels 406 were aligned in a straight line. As can be seen in FIG. 1A, the channels may all have different lengths and directions, which may all accumulate to the total channel length (L_{TC}).

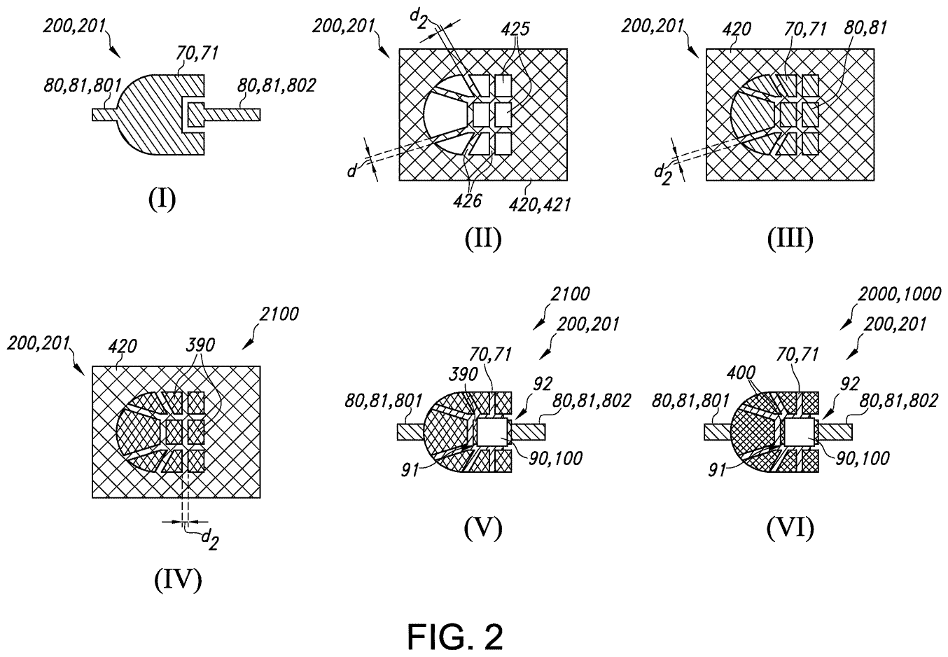

In embodiments, the segmented pattern 401 may comprise one segment 405′ surrounded by three (or more) other segments 405″. In such embodiments, for example, the one segment 405′ may be connected to the three (or more) other segments 405″, such that a fan symbol-like shape is formed, such as depicted in FIG. 1D. Furthermore, FIG. 1D (also) schematically depicts an embodiment where the thermally conductive layer essentially fully (i.e. for 100%) covers the extended printed region 70. Hence, in FIG. 1D both the extended printed region 70 and the thermally conductive layer 400 may have a fan symbol-like shape. FIG. 2 may schematically depict embodiments of the method of manufacturing the electronics arrangement 2000 as described above. Hence, in a yet further aspect, the invention may provide a method of manufacturing the electronics arrangement. The method may especially, in embodiments, comprise a printing stage, a layering stage, an assembly stage, and a curing stage.

During the printing stage, in embodiments, electrically conductive printed tracks 80, and an extended printed region 70 may be printed onto a support board 200, see FIG. 2 subfigure I. Herein, the extended printed region 70 may especially comprise an extended printed region cross-sectional area (A_{T}) defined parallel to (a first face 201 of) the support board 200.

Further, in embodiments, the extended printed region 70 may comprise an extended printed region material 71. Yet further, in embodiments, the electrically conductive printed tracks 80 may comprise an electrically conductive printed track material 81.

In embodiments, during the layering stage, a layer mask 420 (as depicted in FIG. 2 subfigure II) may be applied over at least part of the extended printed region 70, see FIG. 2 subfigure III. Subsequently, in embodiments, a thermally conductive layer precursor material 390 may be applied over the layer mask 420, see FIG. 2 subfigure IV.

After removal of the layer mask 420, during an assembly stage, an electronic element 90 may, in embodiments, be configured on the support board 200, see FIG. 2 subfigure V. The electronics element 90 may especially, in embodiments, comprise a first contact 91 and a second contact 92. In embodiments, the electronics element 90 may be (a) configured with its first contact 91 in thermal contact with the thermally conductive layer precursor material 390 and in electrical contact with a first electrically conductive printed track 801, and (b) configured with its second contact 92 in electrical contact with a second electrically conductive printed track 802. In particular, the electronic element 90 may be configured as such to provide an assembly 2100. Further, in embodiments, the electronic element 90 may have an electronic element cross-sectional area (A_{E}) defined parallel to the (first face 201 of the) support board 200.

In embodiments, the layer mask 420 may comprise a segmented mask pattern 421. Especially, the segmented mask pattern 421 may comprise q mask cut-outs 425. More especially, in embodiments, 2≤q≤20. In embodiments, the q mask cut-outs 425 in the segmented mask pattern 421 may be separated by mask channels 426. The mask channels 426 may, in embodiments, have a mask channel width d2. Especially, in embodiments, the mask channel width d2 may be selected from the range of 50-1000 μm. Further, each mask cut-out 425 may, in embodiments, comprise a cut-out area (A_{J}). Especially, in embodiments, the cut-out areas (A_{J}) of all q mask cut-outs 425 together may be substantially equal to the extended printed region cross-sectional area (A_{T}) as defined above, i.e.,

$${\sum }_{j = 1}^{q} {A}_{j} = {A}_{T} .$$

Returning to the method, in embodiments, during the curing stage the thermally conductive layer precursor material 390 may be heated to provide a thermally conductive layer 400, see FIG. 2 subfigure VI. Especially, the thermally conductive layer 400 may comprise a thermally conductive layer material 410. More especially, the thermally conductive layer 400 may, in embodiments, comprise a layer cross-sectional area (A_{S}) defined parallel to (the first face 201 of) the support board 200.

In embodiments, the printing stage may be executed such and the layer mask 420 may be chosen such that a ratio A_{S}/A_{T} of at most 1.1 may be obtained.

Furthermore, in embodiments, the curing stage may comprise heating the thermally conductive layer precursor material 390 to a temperature selected from the range of 120-400° C. for a duration selected from the range of 5 seconds-60 minutes. Yet further, in embodiments, 1.5≤A_{S}/A_{E}≤30.

Results showed a reduced thermal resistance and a prevention of drifting of the electrical component.

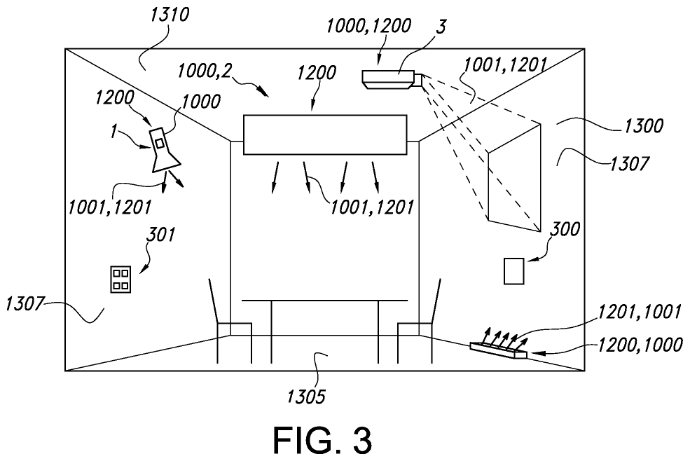

FIG. 3 schematically depicts an embodiment of a luminaire 2 comprising the light generating system 1000 as described above. Reference 301 indicates a user interface which may be functionally coupled with the control system 300 comprised by or functionally coupled to the light generating system 1000. FIG. 3 also schematically depicts an embodiment of lamp 1 comprising the light generating system 1000. Reference 3 indicates a projector device or projector system, which may be used to project images, such as at a wall, which may also comprise the light generating system 1000. Hence, FIG. 3 schematically depicts embodiments of a lighting device 1200 selected from the group of a lamp 1, a luminaire 2, a projector device 3, a disinfection device, a photochemical reactor, an automotive lighting device, and an optical wireless communication device, comprising the light generating system 1000 as described herein. Especially, in embodiments, the light generating system 1000 may comprise a light generating device 100. More especially, in embodiments, the light generating device 100 may be selected from the group of a laser, a LED, a superluminescent diode, a semiconductor chip, and a COB. In embodiments, the lighting device may be a lamp 1, a luminaire 2, a projector device 3, a disinfection device, or an optical wireless communication device. Lighting device light escaping from the lighting device 1200 is indicated with reference 1201. Lighting device light 1201 may essentially consist of system light 1001, and may in specific embodiments thus be system light 1001. Reference 1300 refers to a space, such as a room.

The term “plurality” refers to two or more. The terms “substantially” or “essentially” herein, and similar terms, will be understood by the person skilled in the art. The terms “substantially” or “essentially” may also include embodiments with “entirely”, “completely”, “all”, etc. Hence, in embodiments the adjective substantially or essentially may also be removed. Where applicable, the term “substantially” or the term “essentially” may also relate to 90% or higher, such as 95% or higher, especially 99% or higher, even more especially 99.5% or higher, including 100%. The term “comprise” also includes embodiments wherein the term “comprises” means “consists of”. The term “and/or” especially relates to one or more of the items mentioned before and after “and/or”. For instance, a phrase “item 1 and/or item 2” and similar phrases may relate to one or more of item 1 and item 2. The term “comprising” may in an embodiment refer to “consisting of” but may in another embodiment also refer to “containing at least the defined species and optionally one or more other species”. Furthermore, the terms first, second, third and the like in the description and in the claims, are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein. Use of the verb “to comprise” and its conjugations does not exclude the presence of elements or steps other than those stated in a claim. Unless the context clearly requires otherwise, throughout the description and the claims, the words “comprise”, “comprising”, and the like are to be construed in an inclusive sense as opposed to an exclusive or exhaustive sense; that is to say, in the sense of “including, but not limited to”. The article “a” or “an” preceding an element does not exclude the presence of a plurality of such elements.

The devices, apparatus, or systems may herein amongst others be described during operation. As will be clear to the person skilled in the art, the invention is not limited to methods of operation, or devices, apparatus, or systems in operation.

It should be noted that the above-mentioned embodiments illustrate rather than limit the invention, and that those skilled in the art will be able to design many alternative embodiments without departing from the scope of the appended claims.

In the claims, any reference signs placed between parentheses shall not be construed as limiting the claim.

The invention may be implemented by means of hardware comprising several distinct elements, and by means of a suitably programmed computer. In a device claim, or an apparatus claim, or a system claim, enumerating several means, several of these means may be embodied by one and the same item of hardware. The mere fact that certain measures are recited in mutually different dependent claims does not indicate that a combination of these measures cannot be used to advantage. In yet a further aspect, the invention (thus) provides a software product, which, when running on a computer is capable of bringing about (one or more embodiments of) the method as described herein.

The invention also provides a control system that may control the device, apparatus, or system, or that may execute the herein described method or process. Yet further, the invention also provides a computer program product, when running on a computer which is functionally coupled to or comprised by the device, apparatus, or system, controls one or more controllable elements of such device, apparatus, or system.

The invention further applies to a device, apparatus, or system comprising one or more of the characterizing features described in the description and/or shown in the attached drawings. The invention further pertains to a method or process comprising one or more of the characterizing features described in the description and/or shown in the attached drawings.

The various aspects discussed in this patent can be combined in order to provide additional advantages. Further, the person skilled in the art will understand that embodiments can be combined, and that also more than two embodiments can be combined. Furthermore, some of the features can form the basis for one or more divisional applications.

1. An electronics arrangement comprising a support board, an electrically conductive printed track, an extended printed region, an electronic element, and a thermally conductive layer, wherein:
the support board is configured to support the electrically conductive printed track, the extended printed region, and the electronic element;
the electrically conductive printed track is configured on the support board; wherein the electrically conductive printed track comprises an electrically conductive printed track material;
the electronic element is configured in electrical contact with the electrically conductive printed track; wherein the electronic element comprises a cross-sectional area A_{E}, defined parallel to the support board;
the extended printed region is configured on the support board; wherein the extended printed region comprises an extended printed region material; wherein the extended printed region comprises a cross-sectional area A_{T} defined parallel to the support board; and
the thermally conductive layer is at least partly configured on at least part of the extended printed region; wherein the thermally conductive layer comprises a thermally conductive layer material wherein the thermally conductive layer is in thermal contact with the electronic element, wherein the thermally conductive layer comprises a cross-sectional area A_{S} defined parallel to the support board, wherein A_{S}/A_{T}≤1.1, and wherein 1.5≤A_{S}/A_{E}≤30; and
wherein the thermally conductive layer is configured in a segmented pattern, wherein the segmented pattern comprises n segments configured at least partly around the electronic element, wherein the n segments, each comprising the thermally conductive layer material, are at least partially separated by channels not comprising the thermally conductive layer material, wherein 2≤n≤50, and wherein the channels have a width selected from the range of 50-1000 μm; wherein each segment comprises a segment area A, wherein
$${\sum }_{i = 1}^{n} {A}_{i} \leq {A}_{T} .$$

2. The electronics arrangement according to claim 1, wherein the support board comprises a flexible printed circuit board; and wherein (a) the thermally conductive layer has a first thermal conductiveness C₁, a first thermal conductivity k₁, and a layer thickness, wherein C₁=k₁*tₛ; (b) the electrically conductive printed track has a second thermal conductiveness C2, a second thermal conductivity k₂, and a track thickness, wherein C₂=k₂*tₜ; (c) the extended printed region has a third thermal conductiveness C₃, a third thermal conductivity k₃, and a region thickness, wherein C₃=k₃*tᵣ; and (d) C₃/C₂≥1, C₁/C₂≥2, and C₁/C₃≥2.

3. The electronics arrangement according to claim 1, wherein the thermally conductive layer has a thermal conductivity C1 selected from the range of ≥0.001 W/K; and wherein the thermally conductive layer material comprises one or more of the group comprising lead, tin, silver, copper, zinc, bismuth, indium, antimony, phosphorous, cadmium, nickel, gold, and germanium; and wherein A_{S}/A_{T}≥0.4.

4. The electronics arrangement according to claim 1, wherein the thermally conductive layer comprises a low-temperature solder.

5. The electronics arrangement according to claim 1, wherein the n segments are fully separated by the channels not comprising the thermally conductive material.

6. The electronics arrangement according to claim 1, wherein at least a set of two segments are connected via one or more tracks configured within the channel configured between the two segments.

7. The electronics arrangement according to claim 1, wherein the extended printed region has a horse-shoe like shape, defined parallel to the support board, and is at least partly configured around the electronic element; wherein 2.5≤A_{S}/A_{E}≤10; and wherein the electrically conductive printed track material and the extended printed region material are the same materials.

8. The electronics arrangement according to claim 1, wherein the thermally conductive layer has a thickness selected from the range of 10-500 μm; and wherein the electrically conductive printed track has a thickness selected from the range of 5-50 μm.

9. The electronics arrangement according to claim 1, wherein the electrically conductive printed track material comprises electrically conductive particles, wherein the electrically conductive particles comprise one or more of Ag, Cu, Au, and Al, and wherein the electrically conductive particles have a spherical equivalent diameter selected from the range of 1-15 μm.

10. The electronics arrangement according to claim 1, wherein the electronic element comprises a solid state light source.

11. A light generating system; comprising the electronics arrangement; according to claim 10, wherein the light generating system comprises a light generating device configured to generate device light, wherein the light generating device comprises the solid state light source; wherein the solid state light source comprises a first contact and a second contact, wherein the first contact is configured in thermal contact with the thermally conductive layer and in electrical contact with a first electrically conductive printed track, wherein the second contact is configured in electrical contact with a second electrically conductive printed track.

12. The light generating system according to claim 11, wherein the extended printed region has the horse-shoe like shape; wherein the cross-sectional area A_{T} of the extended printed region is selected from the range of 4-1000 mm², wherein the thermally conductive layer comprises the segmented pattern, wherein the channels have a total channel area A_{TC}, wherein 0.001≤A_{TC}/A_{T}≤0.5, and wherein the channels have a total channel length of at least 0.5*√(A_{TC}/π).

13. A lighting device selected from the group of a lamp, a luminaire, a disinfection device, a photochemical reactor, an automotive lighting device, and an optical wireless communication device, comprising the light generating system according to claim 11; wherein the light generating device is selected from the group of a laser, a LED, a superluminescent diode, a semiconductor chip, and a COB.

14. A method of manufacturing an electronics arrangement, comprising:
a printing stage, wherein electrically conductive printed tracks, and an extended printed region, are printed onto a support board; wherein the extended printed region comprises a cross-sectional area defined parallel to the support board;
a layering stage, wherein a layer mask is applied over at least part of the extended printed region; wherein a thermally conductive layer precursor material is applied over the layer mask;
an assembly stage, wherein, after removal of the layer mask, an electronic element, comprising a first contact and a second contact, is (a) configured with its first contact in thermal contact with thermally conductive paste and in electrical contact with a first electrically conductive printed track, and (b) configured with its second contact in electrical contact with a second electrically conductive printed track; wherein the electronic component has a cross-sectional area A_{E} defined parallel to the support board; and
a curing stage, wherein the thermally conductive layer precursor material is heated to provide a thermally conductive layer; wherein the thermally conductive layer comprises a cross-sectional area A_{S} defined parallel to the support board; wherein the printing stage is executed such and the layer mask is chosen such that a ratio A_{S}/A_{T} of at most 1.1 is obtained and wherein 1.5≤A_{S}/A_{E}<30; and
wherein the thermally conductive layer is configured in a segmented pattern, wherein the segmented pattern comprises n segments configured at least partly around the electronic element, wherein the n segments, each comprising the thermally conductive layer material, are at least partially separated by channels not comprising the thermally conductive layer material, wherein 2≤n≤50, and wherein the channels have a width selected from the range of 50-1000 μm, wherein each segment comprises a segment area Aᵢ, wherein
$${\sum }_{i = 1}^{n} {A}_{i} \leq {A}_{T} .$$

15. The method according to claim 14, wherein the curing state comprises heating thermally conductive layer precursor material to a temperature selected from the range of 120-400° C. for a duration selected from the range of 5 seconds-60 minutes; and wherein 1.5≤A_{S}/A_{E}≤30.
